(19) United States
(12) Patent Application Publication
(10) Pub. No.: US 2015/0122211 A1
(43) Pub. Date: May 7, 2015

(54) SLIDING BODY WITH COATING

(71) Applicant: Mahle International GmbH, Stuttgart (DE)

(72) Inventor: Kurt Maier, Leonberg (DE)

(21) Appl. No.: 14/399,946

(22) PCT Filed: May 7, 2013
(86) PCT No.: PCT/EP2013/059510

§ 371 Date: Nov. 7, 2014

(30) Foreign Application Priority Data
May 10, 2012 (DE) 10 2012 207 813.4

(51) Int. Cl. F16J 9/26; C23C 16/44

(52) U.S. Cl. CPC F16J 9/26; C23C 16/44
USPC 123/193.4; 427/255.28

(57) ABSTRACT

A sliding body for an internal combustion engine may include a main part and a coating which at least partially covers the main part. The coating may have a first main layer. The first main layer may include main components which are molybdenum, nitrogen and oxygen.

### CROSS-REFERENCE TO RELATED APPLICATIONS

This application claims priority to German Patent Application No. 10 2012 207 813.4, filed May 10, 2012, and International Patent Application No. PCT/EP2013/059510, filed May 7, 2013, both of which are hereby incorporated by reference in their entirety.

### TECHNICAL FIELD

The present invention relates to a sliding body, in particular for an internal combustion engine, which sliding body has a main part and a coating. The invention further relates to a method for the production of such a sliding body.

### BACKGROUND

Sliding bodies find a variety of applications and are known sufficiently from the prior art. Such a sliding body for an internal combustion engine is used for example in the combustion chamber of the internal combustion engine and can be constructed in particular as a piston ring. It is typical for such sliding bodies that they slide along another body, whereby friction occurs between these bodies. Here, the longevity of such sliding bodies under high mechanical and thermodynamic stresses is desired. For this purpose, such a sliding body can have a coating which is applied onto a main part of the sliding body.

From EP 0 884 400 B1 a coating is known, which is applied for example onto a piston ring. The coating has a mixture of crystalline chromium nitride and crystalline molybdenum nitride, wherein the crystal structures of at least one of the elements contain oxygen and carbon in the form of a solid solution.

### SUMMARY

The present invention concerns the problem of indicating for a sliding body of the type named in the introduction an improved or at least alternative embodiment, which is distinguished in that the sliding body has an extended lifespan and/or a better sliding characteristic.

This problem is solved according to the invention by the subjects of the independent claims. Advantageous embodiments are the subject of the dependent claims.

The present invention is based on the general idea of providing a main part of a sliding body with a coating which has a first main layer, the main components of which guarantee on the one hand a sufficient stability or respectively hardness and on the other hand an improved sliding characteristic of the coating, in particular of the first main layer, and therefore of the sliding body on another body. The first main layer or respectively its surface, with the use of the main part, is in contact with another body, along which the latter slides. According to the invention, this problem is solved in that the first main layer has the main components of molybdenum, nitrogen and oxygen. The main component means here that the first main layer consists predominantly, preferably exclusively, of these materials or respectively of compounds of these materials. However, the first main layer can also have other lesser or more negligible components or respectively impurities by comparison with these main components. The invention makes use here firstly of the knowledge that molybdenum monoxide-like compounds, in particular molybdenum monoxide, have a self-lubricating characteristic. Accordingly, the coating of the sliding body is to be containing molybdenum monoxide on its outer surface, i.e. facing away from the main part, in order to improve the sliding characteristics of the sliding body and therefore to reduce a friction of the sliding body on an associated other body. Accordingly, the coating is preferably arranged on the regions of the sliding body which slide along this other body. The sliding body can, however, also have entirely such a coating.

Along the thickness of the first main layer, the concentration of the respective main components of the first main layer can vary. For example, the oxygen concentration of the first main layer can decrease in stages or continuously towards the main part, and in particular can be zero. In this sense, the first main layer is a layer with the main components molybdenum and nitrogen, which is doped with oxygen. In other words, the first main layer can have in particular the main component molybdenum nitride and, in particular in the surface region, can be doped with oxygen.

The first main layer preferably has a thickness of 1 μm to 50 μm. The thickness of the first main layer can vary here. In addition, the coating can also partially cover the main part, so that the thickness of the first main layer or respectively of the coating can also be zero in the non-coated regions. In addition, the layer hardness of the coating is preferably between 1,500 and 2,200 HV at 0.05 N test load.

The main part of the sliding body is usually produced from a metallic reusable material. This can be realized for example by a casting process, whereby the main part is configured as a cast body and can be produced from iron and/or steel. In addition, the main part can be nitrided. In so far as the main part consists of steel, it is usually produced in a rolling process. In order to improve an adhesion of the coating to the main part, the coating can optionally have a second main layer, which is arranged expediently between the main part and the first main layer. The second main layer can also be arranged here partially between the first main layer and the main part. The second main layer expediently has a main component which guarantees a sufficient adhesion of the coating to the main part. In particular in the case of a main part produced from metallic materials, the second coating can therefore have a metallic main content. The metallic main content of the second main layer is therefore in particular molybdenum and/or chromium and/or titanium and/or a chromium-aluminium alloy and suchlike.

The thickness of the second main layer is preferably small by comparison with the thickness of the first main layer. Thus, the thickness of the second main layer in preferred embodiments is between 0.5 μm and 10 μm. In preferred embodiments, the second main layer has nitrogen. This means that the second main layer can be doped with nitrogen, so that the second main layer can contain metal nitride at least in certain areas. Preferably, the concentration of nitrogen within the second main layer increases towards the first main layer. In particular, this serves the purpose of improving an adhesion of the first main layer on the second main layer and therefore an adhesion between these main layers. Preferably, the metallic main component of the second main layer is chromium. Accordingly, the coating between the second main layer and the first main layer has a transition from chromium nitride to molybdenum nitride, in order to achieve a particularly advantageous adhesion.

The increase of the nitrogen concentration of the second main layer towards to the first main layer can take place in stages or continuously. Accordingly, the second main layer can have a first sublayer, which contains metal nitride, in particular chromium nitride, and is adjacent to the first main layer. A second sublayer of the second main layer, adjacent to the main part, can in addition be low in nitrogen or free of nitrogen. Whilst the second sublayer of the second main layer therefore guarantees the adhesion to the main part, the first sublayer of the second main layer serves the purpose of creating as great an adhesion as possible between the second main layer and the first main layer.

A further possibility for increasing the adhesion between the first main layer and the second main layer consists in reducing the concentration of molybdenum in the first main layer towards the main part or respectively towards the second main layer. Accordingly, the concentration of the metallic main content of the second main layer can also decrease towards the first main layer. Preferably, the concentration of molybdenum in the first main layer decreases towards the second main layer, whilst the concentration of the metallic main component of the second main layer decreases towards the first main layer. Consequently, a flowing transition between the second main layer and the first main layer is therefore achieved, in order to create a stable coating. Through the adaptation of the concentrations of molybdenum in the first main layer and of the metallic main content in the second main layer in a transition region between these main layers, in particular a lattice mismatch between the second main layer and the first main layer is avoided or at least reduced. If the metallic main content of the second main layer is molybdenum, then such a transition is not necessary.

According to a further preferred embodiment, the first main layer has along its thickness at least two different oxygen concentrations. This means that embodiments are conceivable in which the oxygen concentration within the first main layer increases and decreases again several times. Embodiments are preferred here in which the oxygen concentration oscillates at least in certain regions along the thickness of the first main layer. This means in particular that the oxygen concentration alters periodically between a maximum value and zero. In other words, the first main layer has individual layers along its thickness which are doped with oxygen which alternate with other individual layers which are not doped with oxygen. Consequently a multi-layered layer is created, which is preferably arranged within a first sublayer of the first main layer, which is arranged in a region of the main layer facing away from the main part or respectively in the region of the surface of the first main layer. The periodicity of this multilayered layer is preferably between 50 nm and 300 nm. The periodicity here is given in particular by the sum of an individual layer thickness of an individual layer doped with oxygen and the individual layer thickness of the adjacent individual layer with less oxygen content, in particular of the oxygen-free individual layer. The respective individual layer thicknesses can vary here and in particular can be different between the individual layers doped with oxygen and the individual layers with less oxygen content, in particular the oxygen-free individual layers. With this periodic configuration of the first main layer, the knowledge is utilized that molybdenum nitride has a greater hardness than molybdenum monoxide or respectively than the respective individual layer which is doped with oxygen, whilst the individual layer which is doped with oxygen, which preferably contains molybdenum monoxide, has a better lubrication characteristic. Accordingly, through the alternating arrangement of individual layers containing molybdenum monoxide and individual layers which are free of oxygen or respectively have less oxygen, both a sufficient hardness and also a sufficient self-lubricating characteristic of the first main layer is achieved.

According to a further preferred embodiment, the surface of the first main layer of the coating has a roughness which is worked into this surface for example by fine grinding and/or lapping and/or honing and/or polishing. A mean depth of roughness Rz here is preferably less than 1 μm. In addition, the material content Rmr in a depth of 0.2 μm, i.e. an Rmr 02 value, is greater than 60% and in a depth of 0.3 μm, i.e. an Rmr 03 value, is greater than 80%. The definition and determining of the material content Rmr can be seen here in particular from the Standard DIN EN ISO 4287.

The sliding body can basically be any object sliding on another body. In particular, the sliding body can be configured as a piston ring for a piston of an internal combustion engine, wherein the coating is applied in particular on an outer periphery of the piston ring facing the associated body, on which the piston ring slides, in particular an associated cylinder. The coating improves here the wear resistance of the piston ring and reduces the friction between the piston ring and the associated cylinder of the internal combustion engine.

The coating of the sliding body can basically be applied onto the main part in any desired manner. Gaseous, liquid and dissolved and solid coating methods are indicated here as examples. The coating can take place in particular by means of a chemical vapour deposition or respectively a combustion chemical vapour deposition. The coating can also be applied onto the main part in a spraying process.

The coating preferably takes place by means of a physical vapour deposition (PVD). Here, the main part, which is typically designated as a substrate, is introduced into a suitable chamber. The physical vapour deposition usually takes place here under vacuum-like condition, wherein the main part can be prepared, i.e. cleaned and/or heated, before the vapour deposition of the coating.

The respective metallic contents of the coating, i.e. the metallic main component of the second main layer and molybdenum of the first main layer, are applied by the vaporization of a corresponding metallic target in the chamber onto the main part. Preferably, the vaporization of the respective target takes place by means of an arc, i.e. for instance by the so-called Arc PVD method. When the coating has both the first main layer and also the second main layer, firstly the vapour deposition of the second main layer takes place, followed by the vapour deposition of the first main layer. Preferably, the vapour deposition of the second main layer takes place firstly under argon atmosphere and subsequently in a nitrogen atmosphere, wherein under argon atmosphere and/or nitrogen atmosphere typically the presence of argon and/or nitrogen under low pressures is to be understood. A metal nitride layer forms here onto the main part during the vapour deposition in nitrogen atmosphere, whilst during the vapour deposition in the argon atmosphere a metallic, in particular nitride-free layer is vapour-deposited.

Preferably, the vapour deposition of the second main layer continues directly into the vapour deposition of the first main layer. Here, the first main layer is firstly vapour-deposited in nitrogen atmosphere and subsequently additionally in oxygen atmosphere.

During the vapour deposition of the first main layer in the nitrogen atmosphere, the nitrogen pressure is set so that the nitrogen content in the deposited layer is between 20 atom % and 60 atom %. Preferably, the nitrogen pressure is selected so that the nitrogen content is set between 25 atom % and 40 atom %, most especially between 30 atom % and 35 atom %.

When an oxygen doping is carried out during the vapour deposition of the first main layer, i.e. in particular during the vapour deposition of the uppermost layers of the coating, then with a preferably consistent nitrogen partial pressure in addition some oxygen is introduced into the coating chamber. The oxygen partial pressure is set here so that the molybdenum nitride layer is additionally doped with an oxygen content between 0.5 atom % and 5 atom %, preferably however between 0.5 atom % and 2 atom %. The formation of molybdenum monooxide is thus ensured, and the formation of higher molybdenum oxide compounds, which have unfavourable tribological characteristics, is prevented.

To alter the oxygen doping in the first main layer or respectively to alter the oxygen concentration within the thickness of the first main layer, the oxygen content can be altered here, in particular in an oscillating manner.

The content of molybdenum as final main component of the first main layer results as a residual amount from the nitrogen content and the oxygen content. The molybdenum content of the first main layer in the case of a homogeneous layer is therefore between 35 atom % and 79.5 atom %, preferably between 58 atom % and 75.5 atom %, and particularly preferably between 63 atom % and 69.5 atom %. When the first main layer has such a multi-layered layer with oscillating oxygen concentration, the above-mentioned molybdenum content applies for the oxygen-doped individual layers.

For the vapour deposition of the first main layer, a molybdenum target is used which is vaporized in particular by means of the said arc vaporization. Preferably, in the transition between the second main layer to the first main layer, the vaporization of the metallic target of the second main layer is reduced, whilst the vaporization of the molybdenum target is activated and intensified. Therefore, a flowing transition is achieved between the second main layer and the first main layer, wherein the respective decrease or respectively increase of the vaporization rate of the respective target takes place preferably linearly. In addition, the transition takes place preferably in nitrogen atmosphere.

It shall be understood that the coating of the main part according to the invention and the advantages connected therewith is not limited to sliding bodies and can be applied to any desired structural elements or respectively objects, in order to achieve these advantages. The coating can therefore also be applied, in particular vapour-deposited, onto non-sliding structural elements, in order for example to achieve a desired hardness or to use the coating as a protective layer.

Further important features and advantages of the invention will emerge from the subclaims, from the drawings and from the associated figure description with the aid of the drawings.

It shall be understood that the features mentioned above and to be explained in further detail below are able to be used not only in the respectively indicated combination, but also in other combinations or in isolation, without departing from the scope of the present invention.

Preferred example embodiments of the invention are illustrated in the drawings and are explained in further detail in the following description, wherein the same reference numbers refer to identical or similar or functionally identical components.

### BRIEF DESCRIPTION OF THE DRAWINGS

There are shown here, respectively diagrammatically

FIG. 1 a section through a sliding body according to a first embodiment,

FIG. 2 a section through a sliding body according to a second embodiment.

### DETAILED DESCRIPTION

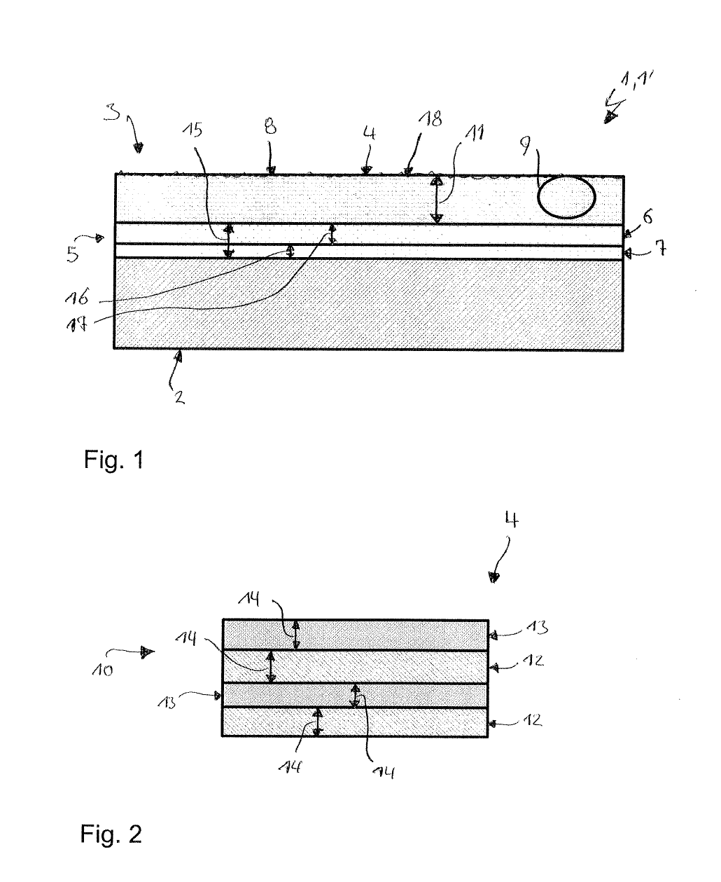

According to FIG. 1, a sliding body 1, which can be configured in particular as a piston ring 1′ for an internal combustion engine, has a main part 2, which is configured for example as a cast body and is produced from iron or respectively steel, wherein the main part 1 can also be nitrided. The sliding body 1 has in addition a coating 3, which is vapour-deposited onto the main part 2. The coating 3 on the main part 2 takes place preferably by means of a physical vapour deposition, in which appropriate targets are vaporized by means of an arc vaporization and are deposited onto the main part 2, in order to form the coating 3.

The coating 3 has here a first main layer 4 and a second main layer 5, wherein the second main layer 5 is arranged between the main part 2 and the first main layer 4. The second main layer 5 comprises two sublayers 6, 7, of which the first sublayer 7 is adjacent to the first main layer 4, whilst the second sublayer 7 is adjacent to the main part 2.

The second main layer 5 has a metallic main content, in particular chromium. The second sublayer 7 of the second main layer 5 is principally or respectively exclusively metallic and consists in particular of chromium, whilst the first sublayer 6 of the second main layer 5 contains nitrogen and accordingly consists in particular of a metal nitride, preferably chromium nitride. The second sublayer 7 of the second main layer 5 serves here for the adhesion of the coating 3 onto the main part 2, whilst the first sublayer 6 of the second main layer 5 is intended in particular to improve an adhesion between the second main layer 5 and the first main layer 4.

The first main layer 4 has the main components molybdenum, nitrogen and oxygen. Here, the oxygen arranged in the region of the first main layer 4 facing away from the main part 2 and therefore in particular in the region of a surface 8 of the first main layer 4 and therefore the surface 8 of the sliding body 1. In addition, the oxygen concentration is small compared with the molybdenum concentration and nitrogen concentration of the first main layer 4, so that the first main layer 4 is doped with oxygen. It is important that the first main layer 4 contains oxygen especially on the surface 8 or respectively directly on the surface 8, wherein the first upper layer 4 preferably has molybdenum monoxide-like compounds in this region, in order to reduce a friction of the sliding body 1 on an associated object, in particular on a cylinder of an internal combustion engine.

FIG. 2 shows a cut-out of the region designated by 9 in FIG. 1 in a further embodiment, which is otherwise identical to that shown in FIG. 1. Here, a multi-layered layer 10 can be seen, which is arranged in the region of the surface 8 of the first main layer 4. The multi-layered layer 10 consists of oxygen-free or respectively low-oxygen first individual layers 12 and second individual layers 13 containing oxygen or respectively doped with oxygen, arranged alternately along a thickness 11 of the first main layer 4. The second individual layer 13, arranged directly on the surface 8, contains oxygen here, in order to ensure the said friction reduction through a self-lubricating characteristic. The periodicity of the multi-layered layer, i.e. the sum of the individual layer thickness 14 of such an individual layer 12 and the individual layer thickness 14 of such an adjacent individual layer 13 is between 50 nm and 300 nm. The individual layers 12 and 13 can have different individual layer thicknesses 14. The proportion of the individual layer thickness 14 of such an individual layer 13 in the periodicity here is preferably between 20% and 60%.

The nitrogen content of the first main layer 4 is between 20 atom % and 60 atom %, preferably between 25 atom % and 40 atom %, particularly preferably between 30 atom % and 35 atom %. In addition, the oxygen content in the first main layer 4, in particular in the oxygen-doped individual layers 13, is between 0.5 atom % and 5 atom %, preferably between 0.5 atom % and 2 atom %. The molybdenum content of the first main layer 4 is between 35 atom % and 79.5 atom %.

As can be further seen in FIG. 1, a thickness 15 of the second main layer 5, which is between 0.5 μm and 10 μm, is smaller than the thickness 11 of the first main layer 4, which is between 1 μm and 50 μm. In addition, a thickness 16 of the second sublayer 7 of the second main layer 5 is smaller than a thickness 17 of the first sublayer 6 of the second main layer 5.

The surface 8 of the first main layer 4 has a roughness 18, which has a mean roughness depth Rz which is less than 1 μm. Furthermore, the material content in 0.2 μm depth is greater than 60%, whilst the material content in 0.3 μm depth is greater than 80%.

1. A sliding body for an internal combustion engine, comprising: a main part and a coating which at least partially covers the main part, wherein the coating has a first main layer, the first main layer including main components which are solely molybdenum, nitrogen and oxygen.

2. The sliding body according to claim 1, wherein the first main layer has a thickness of 1 μm to 50 μm.

3. The sliding body according to claim 1, wherein the first main layer has molybdenum monooxide-like compounds at least in a region facing away from the main part.

4. The sliding body according to claim 1, wherein at least partially between the first main layer and the main part, the coating has a second main layer, which includes a metallic main content including at least one of molybdenum, chromium, titanium and a chromium-aluminium alloy.

5. The sliding body according to claim 4, wherein the second main layer has a thickness between 0.5 μm and 10 μm.

6. The sliding body according to claim 4, wherein the second main layer has nitrogen.

7. The sliding body according to claim 1, wherein the oxygen component of the first main layer includes a concentration that decreases towards the main part.

8. The sliding body according to claim 4, wherein at least one of (i) the molybdenum component in the first main layer has a concentration that decreases towards the main part, and (ii) the metallic main content of the second main layer has a concentration that decreases towards the first main layer.

9. The sliding body according to claim 1, wherein the first main layer has a nitrogen content between 20 atom % and 60 atom %.

10. The sliding body according to claim 1, wherein the first main layer has at least two different oxygen concentrations along its thickness, wherein the oxygen concentration oscillates at least in certain regions along the thickness to define the at least two different oxygen concentrations.

11. The sliding body according to claim 10, wherein a multi-layered layer, formed by the oscillation of the oxygen concentration in the first main layer, has a periodicity between 50 nm and 300 nm.

12. The sliding body according to claim 1, wherein the oxygen concentration component of the first main layer has a concentration that is between 0.5 atom % and 5 atom %.

13. The sliding body according to claim 1, wherein the first main layer has a surface opposite the main part, the surface including a roughness that at least one of: (i) has a mean roughness depth of less than 1 μm, has a material content in a depth of 0.2 μm, and (iii) has a material content in a depth of 0.3 μm.

14. The sliding body according to claim 1, wherein the main part is a piston ring for an internal combustion engine.

15. A method for the production of a sliding body according to claim 1, comprising depositing at least one of the first main layer and a second main layer disposed between the first main layer and the main part and having a metallic main content via physical vapour deposition onto the main part of the sliding body.

16. The method according to claim 15, wherein the first main layer is vapour-deposited in nitrogen atmosphere and additionally in oxygen atmosphere.

17. The sliding body according to claim 1, wherein the first main layer includes a surface opposite the main part, wherein the surface contains molybdenum monooxide compounds.

18. The sliding body according to claim 2, further comprising a second main layer disposed between the first main layer and the main part, the second main layer including at least one of molybdenum, chromium, titanium and a chromium-aluminium alloy.

19. The sliding body according to claim 4, wherein the second main layer includes a nitrogen concentration that increases in a direction towards the first main layer.

20. A sliding body for an internal combustion engine, comprising:
a main part and a coating disposed on the main part, the coating including:
a first main layer including main components constituting solely molybdenum, nitrogen and oxygen, the first main layer having a surface disposed opposite the main part, the surface containing molybdenum monooxide compounds, wherein at least one of (i) a concentration of oxygen in the first main layer decreases in a direction towards the main part, and (ii) a concentration of molybdenum in the first main layer decreases in a direction towards the main part;
a second main layer disposed between the first main layer and the main part, the second main layer including a first sublayer adjacent to the first main layer and a second sublayer adjacent to the main part;
wherein the first sublayer contains a metal nitride and the second sublayer contains at least one of chromium, titanium and molybdenum.
